(19) United States
(12) Patent Application Publication
(10) Pub. No.: US 2024/0411967 A1
(43) Pub. Date: Dec. 12, 2024

(54) HIGH-LEVEL SYNTHESIS OF DESIGNS USING LOOP-AWARE EXECUTION INFORMATION

(71) Applicant: Xilinx, Inc., San Jose, CA (US)

(72) Inventors: Lin-Ya Yu, San Jose, CA (US); Alexandre Isoard, San Jose, CA (US); Hem C. Neema, San Jose, CA (US)

(73) Assignee: Xilinx, Inc., San Jose, CA (US)

(21) Appl. No.: 18/333,372

(22) Filed: Jun. 12, 2023

(51) Int. Cl. G06F 30/323

(52) U.S. Cl. CPC G06F 30/323

(57) ABSTRACT

High-level synthesis of designs using loop-aware execution information includes generating, using computer hardware, an intermediate representation (IR) of a design specified in a high-level programming language. The design is for an integrated circuit. Execution information analysis is performed on the IR of the design generating analysis results for functions of the design. The analysis results of the design are transformed by embedding the analysis results in a plurality of regions of the IR of the design. Selected regions of the plurality of regions are merged based on the analysis results, as embedded, for the selected regions. The IR of the design is scheduled using the analysis results subsequent to the merging.

### RESERVATION OF RIGHTS IN COPYRIGHTED MATERIAL

A portion of the disclosure of this patent document contains material which is subject to copyright protection. The copyright owner has no objection to the facsimile reproduction by anyone of the patent document or the patent disclosure, as it appears in the Patent and Trademark Office patent file or records, but otherwise reserves all copyright rights whatsoever.

### TECHNICAL FIELD

This disclosure relates to integrated circuits (ICs) and, more particularly, to high-level synthesis of designs for ICs.

### BACKGROUND

High-Level Synthesis (HLS) refers to a technology that converts an untimed design specified in a high-level programming language into a fully timed implementation (e.g., a circuit design) specified in a hardware description language. The circuit design may then be realized, i.e., physically implemented, within target hardware such as an integrated circuit (IC). The quality of implementation of the circuit design within the target hardware often depends on the ability of the implementation tools to recognize particular characteristics in the high-level programming language source code of the untimed design that are transformed into, or take advantage of, particular features available in the target hardware.

For example, the implementation tools may attempt to employ certain design optimization techniques such as loop pipelining. Loop pipelining refers to the technique in which the implementation tools attempt to improve performance of the design as physically realized in the target hardware by implementing parallel execution/operation of loop iterations defined in the design. Rather than executing one loop iteration after another sequentially in a non-overlapping manner in the target hardware, the implementation tools attempt to create a timed implementation of the design that utilizes parallelism and allows overlapping loop iterations to improve throughput of the loop and overall design as physically realized in the target hardware.

One way of characterizing loop parallelism uses a metric called the “loop initiation interval” or “loop II.” In general, the II is the number of clock cycles that a design must execute before the design can accept additional or new data for processing. The loop II is the number of clock cycles required between two consecutive loop iteration starts. Loop II describes the rate at which new data may be accepted into a loop. Appreciably, the loop II influences the II of the design and, as such, data throughput.

In the context of HLS, the loop II that is achieved depends on a variety of different and potentially conflicting parameters. For example, aspects of design implementation relating to resource contention on the target hardware and data dependencies between loop iterations may influence the loop II. Also, users may specify particular design constraints to be observed by the implementation tools that influence the loop II. The user-specified design constraints may be explicit loop II requirements and/or resource usage constraints that influence the amount of resources of the target hardware that are available for loop pipelining.

Current implementation tools that perform HLS interpret these different parameters and constraints as if the design has different portions with differing and potentially conflicting II requirements. Because of the apparent conflicts, current implementation tools generate a physical realization of the design that assumes that the portions of the design with higher IIs (e.g., the lower throughput portions) are executed in every loop iteration when called in a loop. This results in a lower overall data throughput of the physical realization of the design.

### SUMMARY

In one or more example implementations, a method includes generating, using computer hardware, an intermediate representation of a design specified in a high-level programming language. The design is for an integrated circuit. The method includes performing, using the computer hardware, execution information analysis on the intermediate representation of the design. The execution information analysis generates analysis results for functions of the design. The method includes transforming the analysis results of the design by embedding the analysis results in a plurality of regions of the intermediate representation of the design. The method includes merging selected regions of the plurality of regions based on the analysis results, as embedded, for the selected regions. The method includes scheduling the intermediate representation of the design using the analysis results subsequent to the merging.

The foregoing and other implementations can each optionally include one or more of the following features, alone or in combination. Some example implementations include all the following features in combination.

In some aspects, the regions are single entry, single exit regions.

In some aspects, the transforming includes translating the analysis results into intrinsic pairs. Each intrinsic pair includes a begin intrinsic and an end intrinsic. Each intrinsic pair is included within the intermediate representation.

In some aspects, the merging merges a first intrinsic pair corresponding to a first region with a second intrinsic pair corresponding to a second region.

In some aspects, the method includes first determining that the first intrinsic pair and the second intrinsic pair comply with merge criteria.

In some aspects, for each intrinsic pair, the begin intrinsic is inserted in a region immediately before a begin instruction of the region and the end intrinsic is inserted into the region immediately before an end terminator instruction of the region.

In some aspects, the analysis results include phase execution information and execution interval information.

In some aspects, the scheduling includes scheduling one or more regions of the plurality of regions in fewer cycles based on the analysis results as embedded.

In some aspects, the method includes generating a circuit design from the intermediate representation as scheduled.

In some aspects, the method includes implementing the circuit design, as scheduled, within an integrated circuit.

In one or more example implementations, a system includes one or more hardware processors configured (e.g., programmed) to initiate and/or execute operations as described within this disclosure.

In one or more example implementations, a computer program product includes one or more computer readable storage mediums having program instructions embodied therewith. The program instructions are executable by computer hardware, e.g., a hardware processor, to cause the computer hardware to initiate and/or execute operations as described within this disclosure.

This Summary section is provided merely to introduce certain concepts and not to identify any key or essential features of the claimed subject matter. Other features of the inventive arrangements will be apparent from the accompanying drawings and from the following detailed description.

### BRIEF DESCRIPTION OF THE DRAWINGS

The inventive arrangements are illustrated by way of example in the accompanying drawings. The drawings, however, should not be construed to be limiting of the inventive arrangements to only the particular implementations shown. Various aspects and advantages will become apparent upon review of the following detailed description and upon reference to the drawings.

FIG. 1 illustrates an example framework for a computer-based Electronic Design Automation (EDA) system.

FIG. 2A illustrates an example of a design specified in a high-level programming language.

FIG. 2B illustrates an example schedule for a function of the design of FIG. 2A.

FIG. 3 illustrates another example of a design specified in a high-level programming language.

FIG. 4 illustrates an example of an intermediate representation (IR) of a design as generated by a high-level synthesis (HLS) compiler.

FIGS. 5A and 5B, taken collectively, illustrate an example of analysis results generated by the HLS compiler.

FIG. 6 illustrates an example of an IR of a design with embedded analysis results.

FIG. 7 illustrates an example transformation of an IR of a design.

FIG. 8 illustrates an example of a merging operation as performed by the HLS compiler.

FIG. 9 illustrates another example of a design specified in a high-level programming language.

FIG. 10 illustrates an example method of performing a transformation operation as implemented by the HLS compiler.

FIG. 11 illustrates a method of performing a merger operation as implemented by the HLS compiler.

FIG. 12 illustrates an example implementation of a data processing system for use with the inventive arrangements.

FIG. 13 illustrates an example method of certain operative features of the HLS compiler of FIG. 1 as executed by the system of FIG. 12.

### DETAILED DESCRIPTION

While the disclosure concludes with claims defining novel features, it is believed that the various features described within this disclosure will be better understood from a consideration of the description in conjunction with the drawings. The process(es), machine(s), manufacture(s) and any variations thereof described herein are provided for purposes of illustration. Specific structural and functional details described within this disclosure are not to be interpreted as limiting, but merely as a basis for the claims and as a representative basis for teaching one skilled in the art to variously employ the features described in virtually any appropriately detailed structure. Further, the terms and phrases used within this disclosure are not intended to be limiting, but rather to provide an understandable description of the features described.

This disclosure relates to integrated circuits (ICs) and, more particularly, to high-level synthesis (HLS) of designs for ICs. In accordance with the inventive arrangements described within this disclosure, methods, systems, and computer program products are provided that are capable of implementing a design within an IC by more efficiently applying loop pipelining optimizations. The inventive arrangements are capable of analyzing a design that is untimed to determine or infer information such as execution phase information and execution interval information. By correctly determining this information during HLS, the execution phase information and the execution interval information may be utilized during certain stages of HLS including scheduling and/or binding to generate a timed version of the design, e.g., a circuit design. The circuit design, as physically realized in an IC, provides increased data throughput by virtue of the scheduling and binding performed using the execution phase information and the execution interval information than would otherwise have been achievable had the information not been determined and/or made available.

The inventive arrangements implement a static scheme that is capable of automatically inferring or determining execution phase information and execution interval information for a user design that is loop aware. This information may be used by the implementation tools during stages of HLS such as scheduling and/or binding. Correctly determining and using the phase execution information and the execution interval information allows the implementation tools to avoid any assumptions that reduce data throughput of the realization of the timed design (e.g., assumptions relating to the portions of the design with higher IIs being executed in every loop iteration when called in a loop). By avoiding such assumption(s) and instead using the determined information, higher data throughput may be achieved for the resulting circuit design and for the circuit design as physically realized in the target hardware.

In addition, the inventive arrangements allow for improved throughput to be achieved while also maintaining acceptable levels of IC resource usage. Having the phase execution information and the execution interval information for scheduling and/or binding, redundant resource usage of the target hardware may be avoided. That is, by knowing when regions of the circuit design are executed and the frequency of execution of the circuit design, the physical realization of the circuit design may better leverage resource sharing in the target hardware thereby consuming fewer resources of the target hardware.

The inventive arrangements improve the performance and resource usage of a design without the user having to make any changes to the design. Further, the various merge operations described within this disclosure serve to reduce the number of instructions contained in intermediate representation of the user design thereby allowing the HLS compiler to execute faster and more efficiently in performing the operations that physically realize the design within the target hardware as fewer instructions remain to be processed. Such is the case particularly for designs that contain loops and functions with different target initiation intervals (IIs). The inventive arrangements provide an automated technique in which a smaller II function (providing improved performance) is able to call a higher II function (providing improved resource usage in the target hardware). The inventive arrangements also may be used to improve designs involving loop flattening and/or loop rewind.

Further aspects of the inventive arrangements are described below with reference to the figures. For purposes of simplicity and clarity of illustration, elements shown in the figures have not necessarily been drawn to scale. For example, the dimensions of some of the elements may be exaggerated relative to other elements for clarity. Further, where considered appropriate, reference numbers are repeated among the figures to indicate corresponding, analogous, or like features.

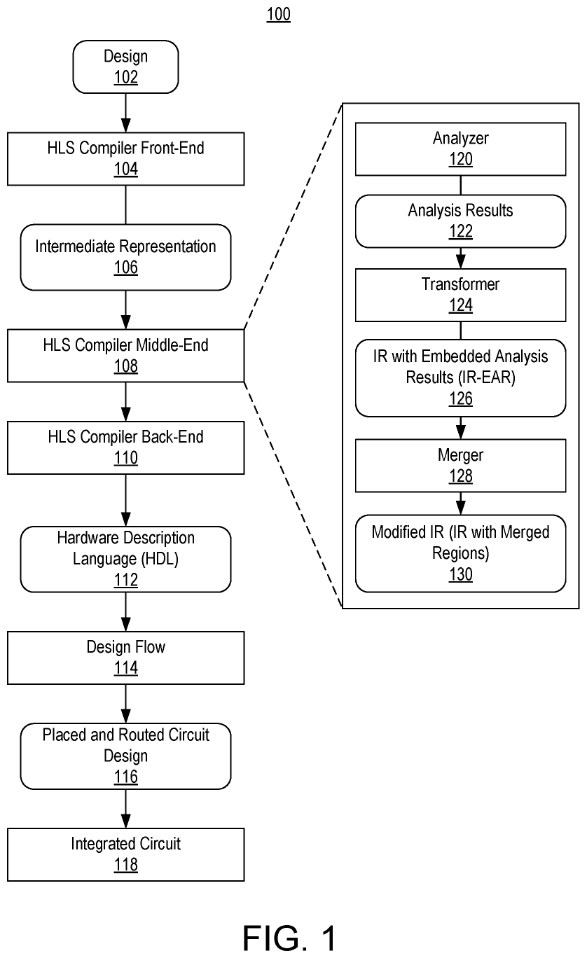

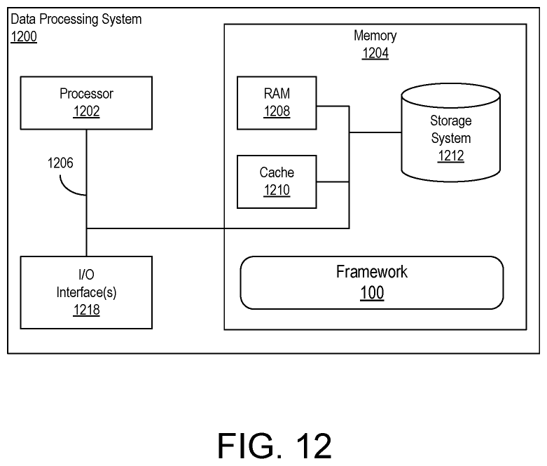

FIG. 1 illustrates an example framework 100 that is executable by an Electronic Design Automation (EDA) system. The EDA system is capable of realizing a user-specified design in hardware. The EDA system may be implemented as a data processing system, e.g., a computer, executing suitable operational software or program code to perform the various operations described within this disclosure. An example of a data processing system that may be used to implement an EDA system and execute framework 100 of FIG. 1 is described in connection with FIG. 12.

In the example of FIG. 1, the EDA system may include an HLS compiler that, when executed, is capable of generating a scheduled version of a design 102 that may be transformed into a hardware description language (HDL) representation of the design. The HLS compiler may include an HLS compiler front-end 104, an HLS compiler middle-end 108, and an HLS compiler back-end 110. The HLS compiler illustrated in FIG. 1 is capable of inferring, e.g., detecting, execution phase information and/or execution interval information, collectively referred to as “execution information,” for a design.

The execution information may be used during scheduling and/or binding of the design for implementation in target hardware (e.g., a target IC). Scheduling refers to a process in which the EDA system determines the start time of operations in a design. Binding refers to a process in which the EDA system maps operations to functional units (e.g., circuit structures), maps variables to storage units, and maps data transfers to buses. Due to the interdependence of scheduling and binding, the order of these operations may be interchanged.

In the example, design 102 is provided to HLS compiler front-end 104. Design 102 may be specified as source code. Design 102 may be a user-specified design intended for implementation in target hardware such as a particular IC. The source code may specified using a high-level programming language. Examples of high-level programming languages include, but are not limited to, C, C++, Python, and OpenCL. Accordingly, design 102 is an untimed high-level specification.

In general, the HLS compiler transforms design 102 into a fully timed implementation. During this transformation, the HLS compiler creates a custom architecture for design 102 to meet particular specification requirements. The architecture generated contains the data path(s), control logic, memory interfaces, and defines how the hardware description language (e.g., RTL) will communicate with systems external to the target hardware. A data path may be formed of a set of storage elements such as (registers, register files, and/or memories), a set of functional units (such as ALUs, multipliers, shifters, and other custom functions), and interconnect elements (such as tristate drivers, multiplexers, and buses). Each component can take one or more clock cycles to execute, can be pipelined, and can have input or output registers. In addition, the entire data path and controller can be pipelined in several stages.

HLS compiler front-end 104 may include a static analyzer and one or more source code analysis tools. HLS compiler front-end 104 is capable of generating an intermediate representation (IR) 106 of design 102. In one aspect, IR 106 may be specified as an LLVM IR as is used by compilers to represent source code for further processing. IR 106 may be specified as a control flow graph (CFG).

In the example, IR 106 is provided to HLS compiler middle-end 108. HLS compiler middle-end 108 is capable of performing a variety of different operations on each function of design 102. The different operations are performed by analyzer 120, transformer 124, and merger 128. Analyzer 120 is capable of performing execution information analysis on IR 106 and, in doing so, generating analysis results 122 for functions of design 102. Analysis results 122, also referred to as execution information, may include execution phase information and execution interval information. Analyzer 120 performs the execution information analysis for each function of design 102.

For example, for each function, analyzer 120 is capable of visiting the loops in a bottom-up manner. Here, “bottom-up” refers to starting with the innermost loop and progressing outward to the outermost loop. For the innermost loop of the function, analyzer 120 analyzes each basic block (BB) in the innermost loop to compute loop-aware execution phase information and execution interval information. For a loop with subloops (e.g., loops other than the innermost loop), analyzer 120 analyzes each subloop and each basic block that belongs to the loop but not to the subloop(s). For purposes of illustration, in the pseudo code of Example 1, analyzer 120 would analyze the code region C0 and subloops SL0 and SL1.

### Example 1

```
for ( ) {
  C0: ...
  SL0: for ( ) {
  }
  SL1: for ( ) {
  }
}
```

Accordingly, Analyzer 120 is capable of generating, for each basic block or loop under a given loop context, execution phase information and execution interval information. Execution phase information is the first loop iteration that executes the basic block and/or loop under the given loop context. Execution interval information is a constant number of loop iterations between the consecutive (in terms of time) basic blocks and/or loop executed loop iterations.

In performing the analysis described herein, analyzer 120 is capable of detecting basic blocks within IR 106. The term “basic block” means a list of one or more instructions of IR 106 in execution order that have a single-entry point and a single exit point. The list of the instructions form the body portion of the basic block.

In one aspect, analyzer 120 is capable of forming regions from the basic blocks. In one or more example implementations, analyzer 120 is capable of generating regions by decomposing each function into single entry, single exit basic block fragments. The fragments are combined to form regions such that, for each region, the exit basic block of the region is guaranteed to post dominate the entry basic block of the region; and the entry basic block of the region is guaranteed to dominate the exit basic block of the region. A node “x” is said to dominate node “y” in a directed graph if every path from “start” to “y” includes “x.” A node “x” is said to post dominate a node “y” if every path from “y” to the “end” includes “x.” The HLS compiler is capable of grouping the plurality of basic blocks into a plurality of regions using the foregoing criteria.

Further aspects of generating regions are described within Pearson et al., “The Program Structure Tree: Computing Control Regions in Linear Time,” Proceedings of the ACM SIGPLAN 1994 conference on Programming language design and implementation, Orlando, Florida, USA (Jun. 20-24, 1994), and Vanhatalo et al., “The Refined Process Structure Tree,” Data Knowl. Eng. 68 793-818 (2009), both of which are fully incorporated herein by reference. Further aspects of basic block analysis are described in U.S. patent application Ser. No. 17/656,236, filed Mar. 24, 2022, which is fully incorporated herein by reference.

Transformer 124 is capable of transforming analysis results 122 of design 102 by embedding analysis results 122 in a plurality of regions of IR 106 to generate IR with embedded analysis results (IR-EAR) 126. Transformer 124 is capable of generating IR-EAR 126 at least in part by translating analysis results 122 into intrinsic pairs. Each intrinsic pair includes a begin intrinsic and an end intrinsic. Transformer 124 is capable of including each intrinsic pair within IR 106. In one aspect, for each intrinsic pair, transformer 124 inserts the begin intrinsic in a region of IR 106 immediately before a begin instruction of the region and inserts the end intrinsic into the region immediately before an end terminator instruction of the region. Through the embedding described, transformer 124 annotates the respective regions with analysis results 122. In the example, each region is a single entry, single exit region.

Merger 128 is capable of merging selected regions of the plurality of regions based on analysis results 122, as embedded (e.g., based on IR-EAR 126), for the selected regions to generate modified IR 130. Modified IR 130 is a version of the IR with merged regions therein. In one or more examples, merger 128 is capable of merging inferred execution information embedded in each basic block inside a single entry, single exit region.

HLS compiler back-end 110 is capable of translating modified IR 130 from HLS compiler middle-end 108 into HDL 112. In an example, HDL 112 may be specified as an RTL description. In generating HDL 112, HLS compiler back-end 110 is capable of scheduling IR 106 using analysis results 122 (e.g., as embodied in a data structure as IR-EAR 126) subsequent to the merging. For example, HLS compiler back-end 110 is capable of detecting particular objects (e.g., intrinsics) within modified IR 130 indicating analysis results 122 and performing operations such as scheduling and/or binding of modified IR 130 to generate HDL 112. HLS compiler back-end 110 is capable of scheduling one or more regions of the plurality of regions in fewer cycles (e.g., using lower IIs) based on the analysis results as embedded.

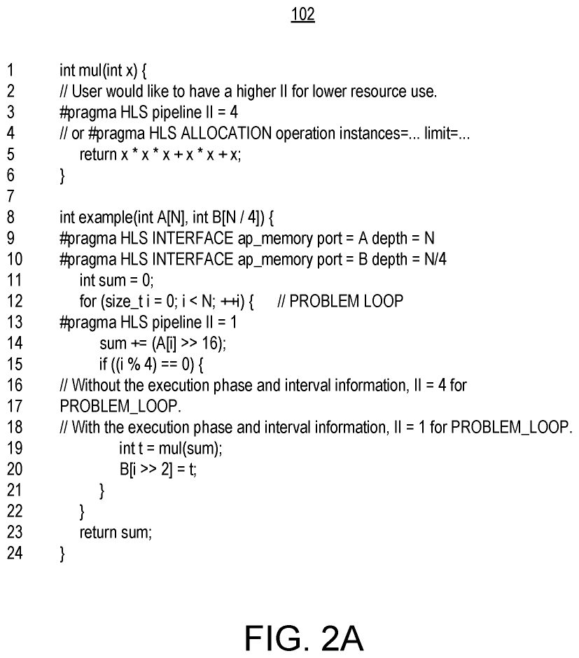

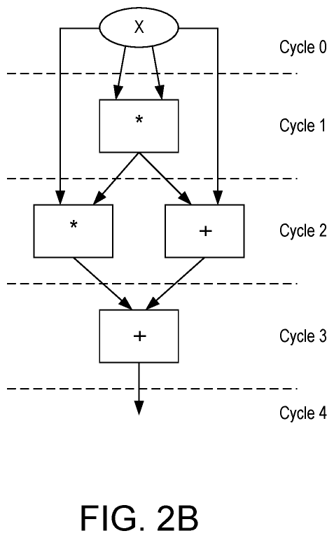

For example, HLS compiler back-end 110 is capable of using the execution interval information of a region to schedule higher II region calls in less/fewer cycles since the region would not be called during the execution interval cycles. HLS compiler back-end 110 is capable of using the execution phase information to determine whether the resource sharing is permissible between compatible execution interval regions. FIGS. 2 and 3 provide illustrations of scheduling higher II region calls in less/fewer cycles and determining whether resource sharing is permissible.

Continuing with the example of FIG. 1, HDL 112 may be processed through a design flow 114. Design flow 114 may include a synthesis process, a placement process, and a routing process. Design flow 114 may generate a placed and routed circuit design 116, as scheduled. In the example, the placed and routed circuit design 116 may be specified in any of a variety of different formats including, for example, as configuration data or a configuration bitstream, that may be loaded into an IC such as IC 118 thereby physically implementing, e.g., realizing, design 102 in IC 118.

IC 118 may be implemented as any of a variety of different types of ICs including, but not limited to, an Application-Specific IC, a System-on-Chip, a programmable IC (e.g., an IC including at least some programmable circuitry such as a field-programmable gate array, where programmable logic is a type of programmable circuitry), or the like.

FIG. 2A illustrates an example of design 102 specified in a high-level programming language. In the example, design 102 includes different pragmas such as a pipeline pragma at lines 3 and 13 specifying IIs of 4 and 1, respectively. The higher II set at line 3 is indicative of the user's intent to reduce resource usage (e.g., higher IIs correspond to lower data throughput and lower resource utilization in the target hardware). The pragma at line 3 specifies an II of 4 for the mul function while the pragma at line 13 specifies an II of 1 for the loop starting at line 12. In this example, due to the modulo function, the mul function within the “problem loop” (designated at line 12) only executes every 4th iteration of the innermost loop.

As indicated by the comments, were conventional HLS performed, the EDA tool would infer an II of 4 for the problem loop owing to the conflicting IIs specified by the pragmas. The EDA tool assumes that the higher II part of the design with an II of 4 is executed in every loop iteration resulting in a lower overall data throughput in the resulting circuit design as realized in the target hardware than would otherwise be possible. That is, the problem loop is implemented with an II of 4 rather than 1. Using the inventive arrangements described herein, analysis results 122 would indicate the execution phase information and the execution interval information for use in scheduling and/or binding thereby allowing the problem loop to be implemented with an II of 1 as specified by the pragma at line 13. This results in a higher data throughput in the resulting circuit design as realized in the target hardware.

In the example of FIG. 2A, good resource usage is also achieved. FIG. 2B illustrates an example scheduling of the mul function of FIG. 2A. Even with an II of 1 on the target loop, the sub function (mul function) can keep an II=4. A single multiplier can handle the operation despite lowering the II from 4 to 1 for the target loop due to hardware sharing. The example schedule illustrated in FIG. 2B for the hardware implementation of FIG. 2A illustrates that the multiplier is used in different cycles (e.g., cycle 1 and in cycle 2). As such, a single multiplier may be used (e.g., shared) to implement the various multiplication operations of the mul function (x*x*x+x*x+x).

FIG. 3 illustrates another example of design 102. The example of FIG. 3 is another version of the example high-level program code of FIG. 2. In the example of FIG. 3, without execution interval information, the loop starting at line 13 (the “target loop”) would be scheduled with an II of 2. This is the case because the mul function needs to be scheduled as II=2 since the user provided allocation pragma at line 5 limits the multiplier usage to a single multiplier instance in the target hardware. The scheduling component of HLS compiler back-end 110 is unable to understand that the execution interval of mul at line 17 is actually 4. In a conventional implementation, the EDA system would conservatively assume the mul function is executed every iteration in the target loop leading to a final II of 2.

In accordance with the inventive arrangements described within this disclosure, the scheduling component of HLS compiler back-end 110 is able to schedule the target loop with an II of 1. Without the determined execution information, to achieve II=1 for the TARGET_LOOP, the mul function would have been required to be scheduled at II=1 as well. To achieve II=1 for the mul function, however, the resource usage need to be increased to two multipliers (see, for example, FIG. 2B). In this example, the II=1 scheduling of the TARGET_LOOP is achieved due to the execution information indicating that the execution interval of the mul function at line 17 is actually 4. Thus, the scheduler component of HLS compiler back-end 110 is able to achieve good performance (II=1) for the TARGET_LOOP and good resource usage (e.g., a single multiplier) by virtue of having an accurate and automated assessment of the execution interval for the mul function as specified by the execution information.

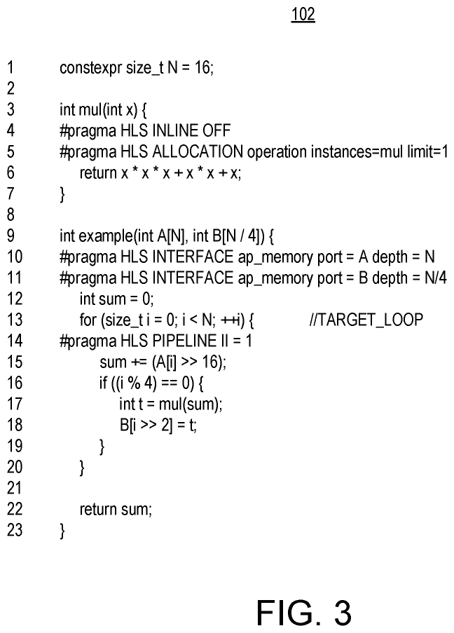

FIG. 4 illustrates an example of IR 106 as generated by HLS compiler front-end 104 from the example design 102 of FIG. 3. Once converted to IR 106, analyzer 120 of HLS compiler middle-end 108 is capable of performing the analysis in a bottom-up manner. In this case, the mul function does not contain a loop. Accordingly, there is nothing in the mul function to analyze. Analyzer 120 continues analyzing each next outer loop, e.g., the if construct at line 16 of FIG. 3 followed by the for construct at line 13, etc., to generate analysis results 122.

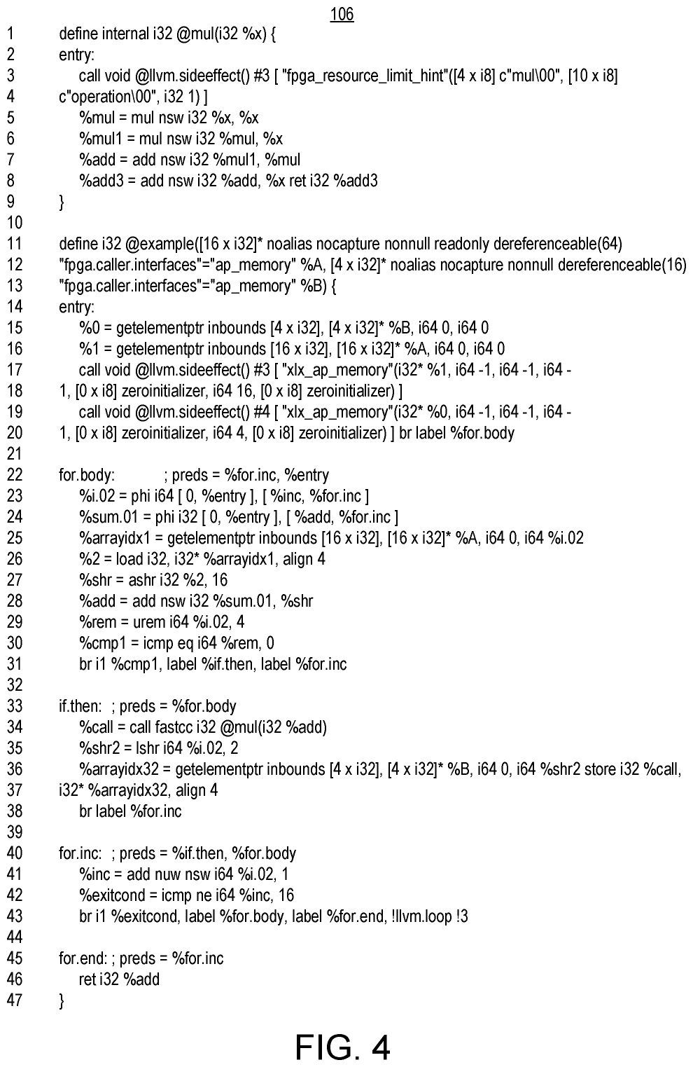

FIGS. 5A and 5B, taken collectively (and collectively referred to as FIG. 5), illustrate an example of the analysis results 122. For purposes of illustration, the analysis results are shown within IR 106 in bold. It should be appreciated that analysis results 122 may be specified in any of a variety of different formats and may or may not be embedded in IR 106 at this time. The execution information is shown in the format {phase, +, interval}, where phase represents the execution phase information and interval represents the execution interval representation.

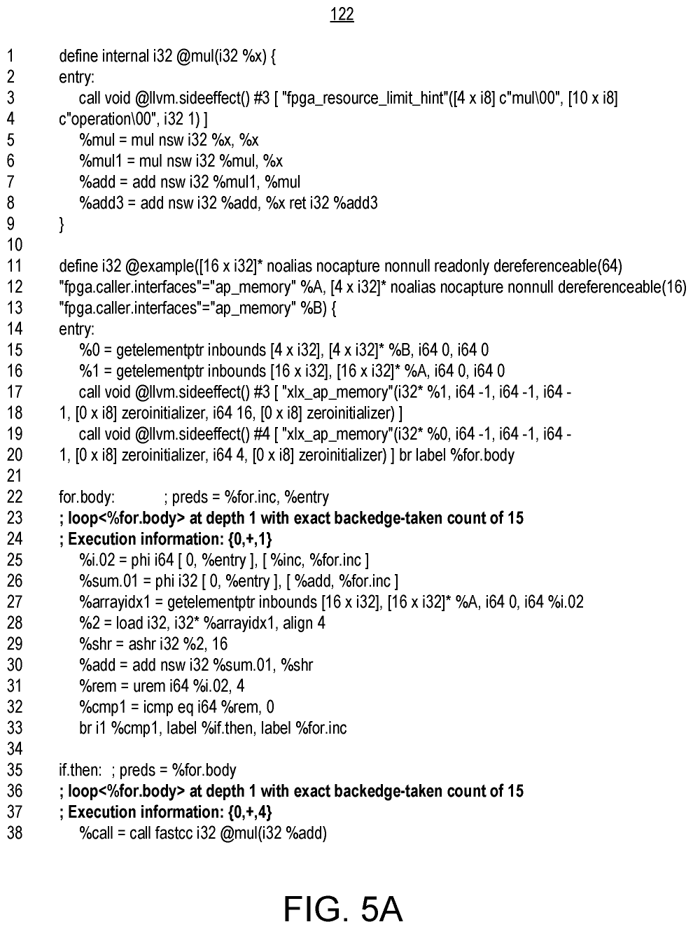

FIG. 6 illustrates an example of IR-EAR 126. In the example of FIG. 6, since the basic block if.then (e.g., corresponding to lines 35-41 of FIG. 5) is analyzed with a non-one execution interval, the basic block can be transformed as illustrated in FIG. 6. In FIG. 6, the analysis results have been transformed into intrinsic pairs. The statements forming the intrinsic pair are shown in bold and correspond to lines 2 and 7. The intrinsic pair includes the begin intrinsic at line 2 immediately preceding the begin instruction of the region (e.g., % call=call fastcc i32 @mul (i32% add) at line 3) and the end intrinsic at line 7 immediately before the end terminator instruction of the region (e.g., br label % for.inc at line 8). The example of FIG. 6 illustrates, at least in part, how analysis results 122 are embedded within IR 106 by transformer 124 to produce IR-EAR 126. In the example of FIG. 6, there is nothing to be merged.

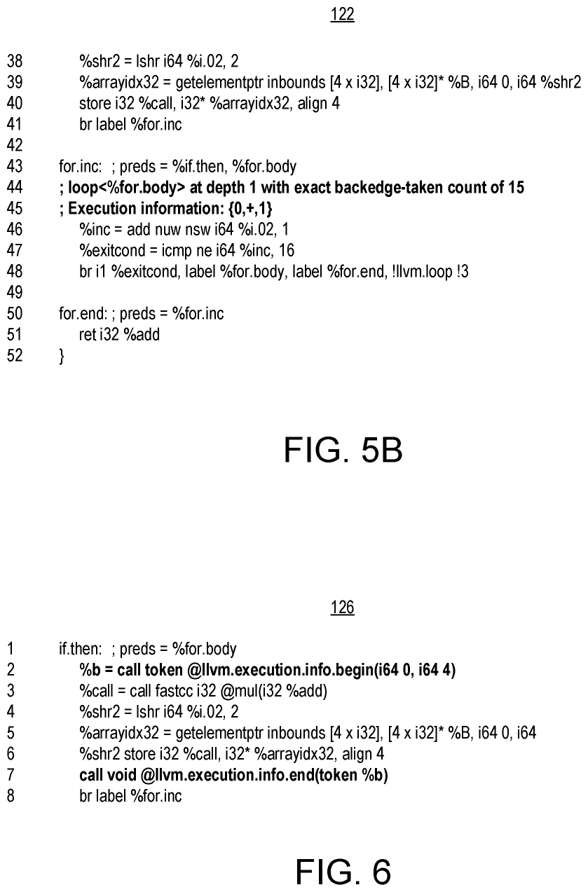

If, however, an optimization is applied to the IR, the if.then may be transformed into the example of FIG. 7. In the example of FIG. 7, having applied the optimization, the if.then is split. The first portion corresponding to lines 1-5 includes a first intrinsic pair with a begin intrinsic at line 2 and an end intrinsic at line 4. The second portion corresponding to lines 7-13 includes a second intrinsic pair with a begin intrinsic at line 8 and an end intrinsic at line 12. Transformer 124 may be configured to implement the operations illustrated in FIG. 7. Compilers, for example, are capable of performing code transformations such as splitting basic blocks or inserting new basic blocks as shown in FIG. 7.

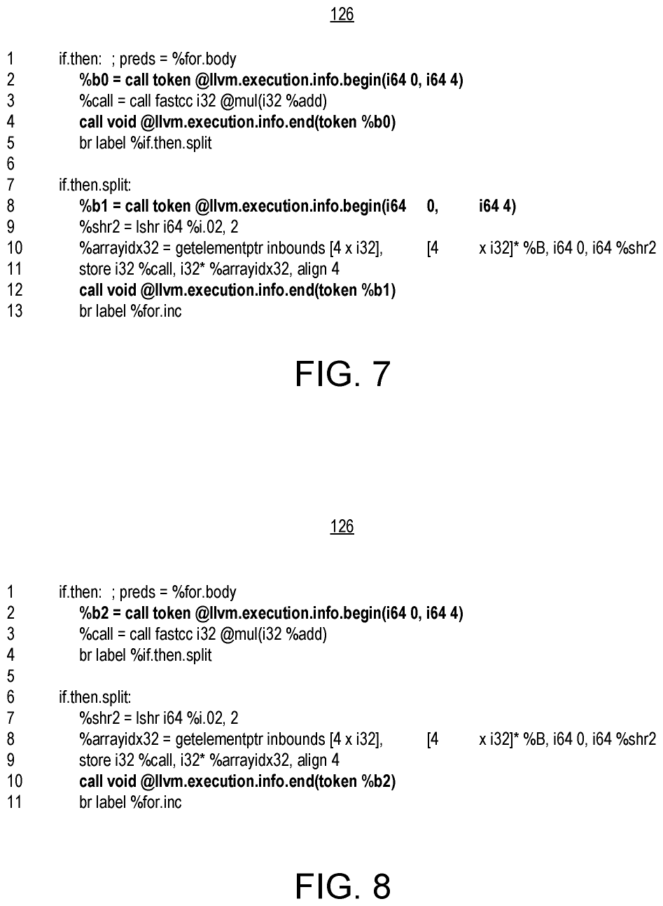

FIG. 8 illustrates an example of the merging operation as performed by merger 128 of HLS compiler middle-end 108. Merger 128, for example, is capable of merging equivalent execution regions into one as illustrated in the example of FIG. 8. In the example, the two intrinsic pairs illustrated in FIG. 7 are merged into a single intrinsic pair having a single begin intrinsic and a single end intrinsic. In the example, the two intrinsic pairs are merged by retaining the begin intrinsic of the first intrinsic pair at line 2 of FIG. 7 and maintaining the end intrinsic of the second intrinsic pair at line 12 of FIG. 7. The end intrinsic of the first intrinsic pair at line 4 of FIG. 7 and the begin intrinsic of the second intrinsic pair at line 8 of FIG. 7 have been removed in the example of FIG. 8.

The scheduling component of HLS compiler back-end 110 schedules IR-EAR 126 as output from merger 128. The scheduling component uses the execution interval information to schedule the mul function to execute (e.g., within the target hardware) executed at a lower rate (Interval=4), which is lower than other instructions around in the loop body to reach II=1 for the TARGET_LOOP.

The examples of FIGS. 7 and 8 demonstrate the ability of the inventive arrangements to merge execution regions to reduce the code size. Reducing code size as described herein reduces the compile time required to process the execution information (e.g., thereby improving computing performance and runtime) in performing HLS to physically realize a design.

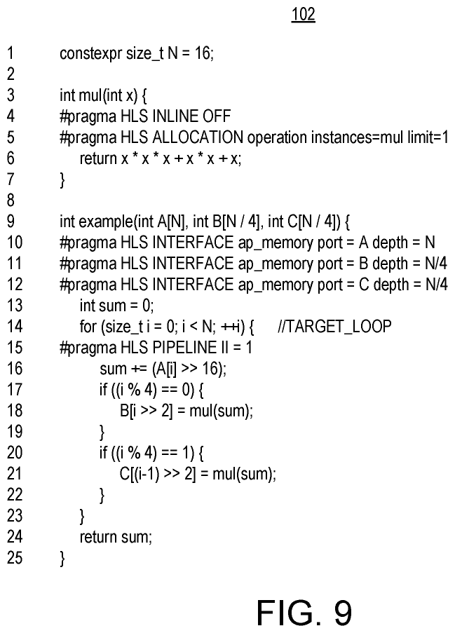

FIG. 9 illustrates another example of design 102. The example of FIG. 9 illustrates the need for execution phase information. Without the execution phase information, the HLS compiler may be unable to determine whether the mul function can be shared. In the example of FIG. 9, the mul function may not be shared due to the starting stages between the two mul executions at lines 18 and 21, respectively, being different in terms of II=2 clock cycles. The mul function of line 18 always starts at even cycles (e.g., i % 4==0), but the mul function of line 21 always starts at odd (e.g., i % 4==1). If the predicate at line 19 is changed into (i % 4)==2, the mul function is sharable since all the mul function executions start at an even clock cycle. Wrongly decided sharing on the part of the HLS compiler may result in consumption of more resources of the target hardware than necessary or incorrect design synthesis at the binding stage.

In general, predication refers to the use of a predicate function that returns a single true or false value based on a set of one or more parameters. Predication works by using the predicate function, e.g., a non-branch instruction associated with a predicate, to determine whether to change the architectural state (e.g., the execution flow) of the design. A “predicate” may refer to a Boolean value used by an instruction to control whether the instruction is allowed to modify the architectural state of the design or not. If the predicate specified in the instruction is true, for example, the instruction modifies the architectural state of the design. If the predicate specified by the instruction is false, the instruction does not modify the architectural state of the design.

As an illustrative and non-limiting example, a predicated move instruction, e.g., a conditional move, will only modify the destination if the predicate is true. Thus, instead of using a conditional branch to select an instruction or a sequence of instructions to execute based on the predicate that controls whether the branch occurs, the instructions to be executed are associated with that predicate, so that the instructions will be executed, or not executed, based on whether the predicate is true or false.

The analysis performed by analyzer 120 is illustrated in the sections below with example pseudo code for querying the execution information under a given loop context for a given loop or basic block (BB). The analysis returns an affine {Phase, +, Interval} to represent the execution phase information and the execution interval information under the loop context. If the analysis returns an “-” in the affine, the execution information is unknown. Otherwise, the execution phase information and the execution interval information are returned as non-negative integers. The analyzer 120 is capable of performing the execution information analysis for a variety of different supported loops. Supported loops have the following characteristics:
A single preheader;
A single back edge (which implies that there is a single latch);
A single dedicated exit; and
A single increasing loop induction variable, where the induction variable evolution can be represented in an affine.

Listings 1-7 include example pseudo code illustrating various operations that may be implemented as part of the execution information analysis performed by analyzer 120. Listing 1 for the function getExecutionInfo(Loop: L) can be applied to analyze the execution information of a subloop under the parent loop context of the subloop.

Listing 1: getExecutionInfo(Loop: L)

```
//Gets execution information for a given loop L
if (!isSupportedLoopForm(L)) // Check mentioned supported loop
form requirements
  return None
PL = getParentLoop(L) // Provided by LLVM Loop class
if (No existing parent Loop PL)
  return None
PreHeaderBB = getPreHeader(L) // Provided by LLVM Loop class
// Computes the execution information for PreHeaderBB under PL
loop context
return compute(PreHeaderBB, PL)
```

Listing 2 for the function getExecutionInfo(BasicBlock: BB) can be applied to analyze the execution information of a basic block under the loop context to which the basic block belongs.

Listing 2: getExecutionInfo(BasicBlock: BB)

```
//Gets execution information for a given Basic Block BB
L = The innermost loop BB belongs to // Provided by LLVM LoopInfo
Analysis if (No existing loop L)
  return None
if (!isSupportedLoopForm(L)) // Check mentioned supported loop form
requirements
  return None
return compute(BB, L)
```

Listing 3 for the function compute (BasicBlock: BB, Loop: L) computes the execution information for a given basic block BB under loop L context.

### Listing 3: Compute(BasicBlock: BB, Loop: L)

```
// Loop L induction variable affine = {Init, +, Stride}. Init is the initial
value of the loop
// induction variable, and Stride is the constant value to which the loop
induction
// variable evolves between iterations. For example, an induction variable
`i` in loop for
// (i = 0; i < N; i++) would be represented as {0, +, 1}.
{Init, +, Stride} = Induction variable affine of L
// Provided by LLVM Scalar Evolution Analysis
if (isExecutedInAllIterations(BB, L))
// Check if the BB is executed at every loop L's iteration
  return {Phase=Init, Interval=1}
// Computes the loop L's induction variable execution value range at BB.
Range is
// represented as [Low, High) which value v is in the range when Low <=
v < High.
// Range = getExecutedLoopIndVarRange(BB, L) computes the first loop
iteration that
// executes things in the ′Range′ (which is the first loop iteration that
executes BB).
Phase = getNumStepsIn(Range, L)
if (couldNotComputeBackedge TakenCount(L))
// Can be constructed by LLVM ScalarEvolution: getBackedgeTakenCount
and
// SCEVCouldNotCompute
  return {Phase, /*Interval=*/1}
LTC = isRotatedLoop(L) ? BTC+1 : BTC // Provided by LLVM Loop
class
If (isSingleElement(Range))
// Check if Rang.High equals Range.Low+1
return {Phase, /*Interval=*/LTC}
Interval = getInterval(BB, L) // Computes the BB execution interval under
loop L.
If (LTC %u Interval == 0) // %u: unsigned remainder return {Phase,
Interval}
return {Phase, /*Interval=*/1}
```

Listing 4 for the function isExecutedinAllIterations (BasicBlock: BB, Loop: L) returns true if the given Basic Block BB is executed at every given loop L's iteration.

Listing 4: isExecutedInAllIterations (BasicBlock: BB, Loop: L)

ExitBB=the unique loop exit basic block of loop L//Provided by LLVM Loop class If BB dominates ExitBB//Provided by LLVM DominatorTree Analysis
return true
   return false

Listing 5 for the function getExecutedLoopIndVarRange (BasicBlock: BB, Loop: L) computes the loop L's induction variable execution value range at BB and returns any computed range. Otherwise, the function returns “None” when the range is unknown. The range is represented as [Low, High) where value v is in the range when Low <=v<High.

Listing 5: getExecutedLoopIndVarRange (BasicBlock: BB, Loop: L)
In a first phase, the getExecutedLoopIndVarRange (BasicBlock: BB, Loop: L) function calculates the iterative post dominance frontiers (IPDFs) of the BB and excludes the IPDF that lives out of the loop or itself is the loop exiting BB (filtered IPDFs).
In a second phase, the function checks that all the filtered IPDFs dominate the BB. This implies that there are only AND relationships between predicates in the CFG paths. The function returns “None” when the check fails as only multiple predicates with AND relationships are supported.
In a third phase, the function collects all the predicates and true/false edges of the predicate to BB from the condition instruction of the terminator instruction in the filtered IPDFs. The function checks if there are any predicates with OR relationships inside an IPDF BB. The function returns “None” when the check passes as only multiple predicates with an AND relationship are supported. The true/false edges of the predicate are analyzed through the dominance relationship between IPDF BB's successors and BB.
In a fourth phase, the function proves the BB is unreachable in L by checking if any opposite polarities exist. If BB is unreachable, the function returns “None.”
In a fifth phase, the function calculates an initial range R from Loop L trip count and loop L induction variable affine={Init, +, Stride} as [Init, Stride×loop L trip count+Init). In this example, “Init” is the initial value of the loop induction variable and “Stride” is the constant value to which the loop induction variable evolves between iterations. For example, an induction variable “i” in the loop for (i=0; I<N; i++) would be represented as {0, +, 1}. The loop L induction variable affine and loop L trip count can be calculated with LLVM Scalar Evolution.
In a sixth phase, the function updates the range R for each “IV <comparison operators> v” predicate, where “IV” is the loop L induction variable and v is the loop L invariant variable. For non-equality or ‘==’ comparison operators, the function gets the maximum value for the Low, and the minimum value for the High. For the “!=” operator, using induction, the function checks that either vis equivalent to Low or v+1 is equivalent to High. If the check passes, the function updates the range R into [v+1, High) or [Low,v). If the check fails, the function returns “None.”
In a seventh phase, the function aligns the Low in the range R to the first value that is greater than or equal to the Low and is on the BB executed induction variable affine (IV′). The aligned Low(AL) is calculated as steps×Stride+Init, where steps is ceiling((Low−Init)/Stride).
In an eighth phase, the function updates the range R for a single “IV % u divisor==remainder” predicate, where IV is the loop L induction variable, the divisor and remainder are static known constants, and % u is unsigned remainder operation. The function calculates the BB executed induction variable modulo affine (MIV′)={MInit, +, MStride}. MInit is calculated as ceiling(max(AL−remainder, 0)/divisor)*divisor+remainder and the MStride is calculated as the least common multiple of the divisor and the Stride. The function proves that the BB is unreachable if the two affines: IV and MIV′ do not have any intersection. Since the intersection of two affines would be either affine or null, this condition can be checked through whether the IV can step on the calculated MInit or not. To check this, the function first computes the number of step IV and whether the number of step IV would be on or over Minit with ceiling ((Mint-Init)/Stride). The function can utilize the LLVM Scalar evolution API: evaluateAtIteration to evaluate the value of IV at the computed number of step(number_of_step). If the evaluated value is the same as Mint, the intersection is found, and updates the Low in the range R as number_of_step×Stride+Init. Else, the function returns “None.”
In phase 9, the function, in response to encountering an unsupported predicate (e.g., one not described above) encountered, returns “None.” Whenever the function encounters more than one “IV % u divisor==remainder” predicate, the function returns “None.”
In phase 10, the range R is returned.

Listing 6 for the function getNumStepsIn (Range: R, Loop: L) computes the first loop iteration in a given Loop L that executes items in the given Range R. The Range is represented as [Low, High) where value v is in the range when Low <=v<High.

Listing 6: getNumStepsIn (Range: R, Loop: L)

// Loop L induction variable affine = {Init, +, Stride}. Init is the initial
value of the loop
// induction variable, and Stride is the constant value that the loop
induction variable
// iterations. For example, how an induction variable ′i′ in loop
for (i = 0; I < N; i++)
// would evolve may be represented as {0, +, 1}.
{Init, +, Stride} = Induction variable affine of L
// Provided by LLVM Scalar Evolution Analysis
return ceiling((R.Low − Init) / Stride)

Listing 7 for the function getInterval (BasicBlock: BB, Loop: L) computes the given Basic Block BB execution interval under the given Loop L context given the loop L induction variable affine={Init, +, Stride}. Init is the initial value of the loop induction variable. Stride is the constant value that the loop induction variable evolves between iterations. For example, an induction variable “i” in loop for (i=0; I<N; i++) would be represented {0, +, 1}.

Listing 7: getInterval (BasicBlock: BB, Loop: L)

{Init, +, Stride} = Induction variable affine of L
// Provided by LLVM Scalar Evolution Analysis
if (BB isn't guarded under single ″IV %u divisor == remainder″ predicate)
// Collection of the predicate can be found in the function
// getExecutedLoopIndVarRange (BasicBlock:BB, Loop:L)
Interval = Stride
// BB is guarded under single ″IV %u divisor == remainder″ predicate
Range = getExecutedLoopIndVarRange(BB, L)
if (Range != None)
Interval = the least common multiple of the divisor and the Stride)
Interval = Interval / Stride
return Interval

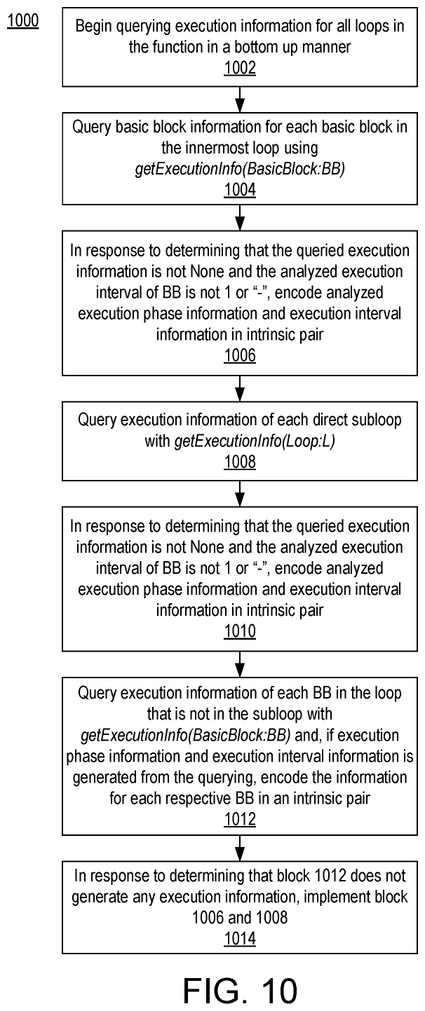

FIG. 10 illustrates an example method 1000 of performing the transformation operation as implemented by transformer 124 of HLS compiler middle-end 108. Method 1000 illustrates the transformation of execution information into intrinsic pairs, each including a begin intrinsic and an end intrinsic that carry the inferred execution information within the IR that is generated. The transformation operation supports single entry, single exit regions.

In block 1002, transformer 124 queries the execution information for all of the loops in the function in a bottom-up manner (e.g., from the innermost loop to the outermost loop). In block 1004, transformer 124 queries the basic block information for each basic block in the innermost loop using getExecutionInfo(BasicBlock: BB) as described in connection with the execution information analysis. In block 1006, in response to determining that the queried execution information is not “None” and that the analyzed execution interval of BB is not 1 or “-”, for each BB, transformer 124 encodes the analyzed execution phase information and the execution interval information in an intrinsic pair. For example, transformer 124 encodes the analyzed execution phase information and execution interval information in the begin intrinsic and inserts the begin intrinsic right before (e.g., immediately prior to) the begin instruction, e.g., the first non-phi instruction, in the BB. Transformer 124 encodes the end intrinsic by taking the begin intrinsic as an input and inserting the end intrinsic right before (e.g., immediately prior to) the end terminator instruction in the BB.

In block 1008, in the case where the loop has one or more subloops, transformer 124 queries the execution information of each direct subloop with the function getExecutionInfo(Loop: L) as provided in the execution information analysis. In block 1010, in response to determining that the queried execution information is not “None” and that the analyzed execution interval of BB is not 1 or “-”, for each subloop, transformer 124 encodes the analyzed execution phase information and the execution interval information in an intrinsic pair. For example, transformer 124 encodes the analyzed execution phase information and execution interval information in the begin intrinsic and inserts the begin intrinsic right before (e.g., immediately prior to) the begin instruction, e.g., the first non-phi instruction, in the BB. Transformer 124 encodes the end intrinsic by taking the begin intrinsic as an input and inserting the end intrinsic right before (e.g., immediately prior to) the end terminator instruction in the BB.

In block 1012, transformer 124 is capable of querying the execution information of each BB in the loop that is not in the subloop with getExecutionInfo(BasicBlock: BB). If execution phase information and execution interval information is generated from the querying, transformer 124 encodes that information for each respective BB in an intrinsic pair.

In block 1014, in response to determining that block 1012 does not generate any execution information, blocks 1006 and 1008 may be performed. For purposes of illustration, consider the pseudo code of Example 1. For a loop with subloops such as LO, transformer 124 queries the execution information of each direct subloop SL0 and SL1 with getExecutionInfo(Loop: L) as provided in the execution information analysis. If the queried execution information is not None and the analyzed execution interval for the BB is not 1 or ‘-’, transformer 124 encodes both the analyzed execution phase and interval in the begin intrinsic and inserts the begin intrinsic right before the first non-phi instruction in the preheader BB of subloop SL0 or SL1. Transformer 124 encodes the end intrinsic by taking the begin intrinsic as an input and inserts the end intrinsic right before the terminator in the exit BB of the subloop SL0 or SL1. Transformer 124 may then query the execution information of each BB in loop C0 but not in the subloop with getExecutionInfo(BasicBlock: BB) as provided in the execution information analysis. In response to determining that there is not any execution information in the BB that is inserted by the operations of block 1012, as determined by block 1014, transformer 124 performs the operations of blocks 1006 and 1008.

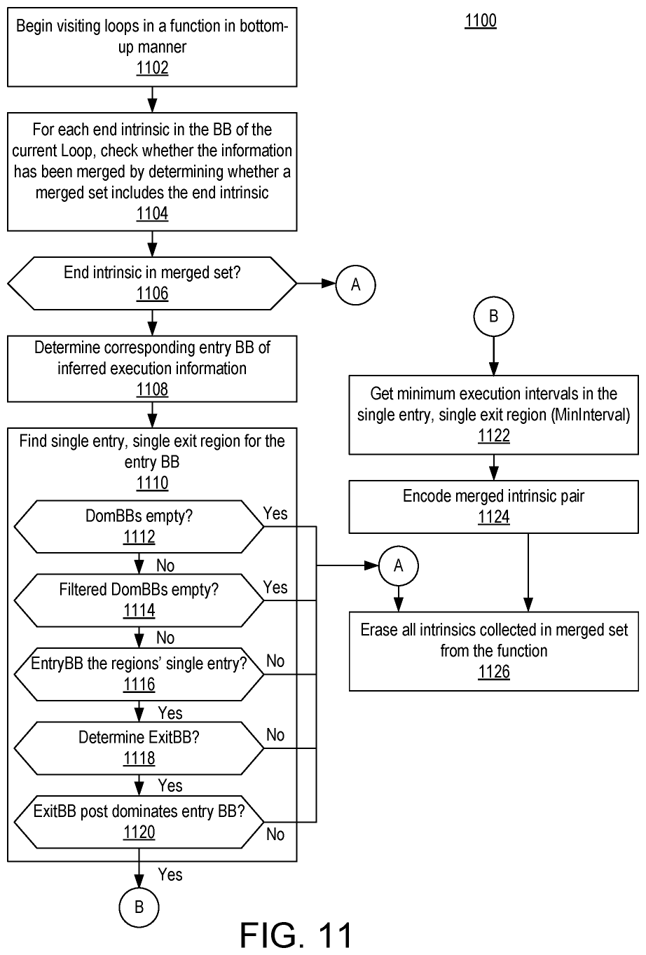

FIG. 11 illustrates a method 1100 of performing the merger operation as implemented by merger 128 of HLS compiler middle-end 108. As discussed, merger 128 is capable of performing the merger operation to merge execution information in a single entry, single exit region.

In block 1102, merger 128 is capable of visiting loops in a function in a bottom-up fashion. In block 1104, for each end intrinsic specifying determined or inferred execution information for a BB of the current loop, merger 128 checks whether the execution information is already merged by determining whether the end intrinsic exists in a merged set (e.g., a set of end intrinsics that have been collected as already having been merged). In block 1106, in response to determining that the end intrinsic is in the merged set, method 1100 continues to block 1126. In response to determining that the end intrinsic is not within the merged set, method 1100 continues to block 1108.

The remaining operations described in connection with FIG. 11 are performed on a per BB basis. In block 1108, merger 128 is capable of determining the corresponding entry BB of the inferred execution information (e.g., as specified by the end intrinsic). For example, merger 128 gets the BB of the end intrinsic user which is where the begin intrinsic is located.

In block 1110, merger 128 finds the single entry, single exit region for the entry BB. In performing block 1110, merger 128 may perform additional operations illustrated as blocks 1112, 1114, 1116, 1118, and 1120.

In block 1112, merger 128 invokes LLVM DominarTree analysis to get all of the BBs that are dominated by the entry BB in order. The in order BBs that are dominated by the entry BB are referred to as a set called “DomBBs.” In response to merger 128 determining that DomBBs is empty, method 1100 continues to block 1126. Otherwise, method 1100 continues to block 1116.

In block 1114, merger 128 generates another set of BBs referred to as the Filtered DomBBs by excluding any BBs from the DomBB that are outside of the Loop. In response to determining that Filtered DomBBs is empty, method 1100 continues to block 1126. Otherwise, method 1100 continues to block 1116.

In block 1116, merger 128 checks whether the EntryBB is the region's single entry by determining whether only a single predecessor exists for the DomBBs.frontBB (i.e., the EntryBB). In response to determining that there is not a single predecessor, method 1100 continues to block 1126. Otherwise, method 1100 continues to block 1118.

In block 1118, merger 128 determines the ExitBB. In one or more examples, merger 128 may implement the process illustrated in the pseudo code of Listing 8.

### Listing 8

```
ExitBB = None
for (SuccBB = each successor(Filtered DomBBs)) {
  if (Filtered DomBBs.contains(SuccBB))
    continue
// Found more than one exit BB in Filtered DomBBs
  if (ExitBB)
    return None
  ExitBB = BB
}
return ExitBB
```

In the event merger 128 obtains a value of “None” for ExitBB, method 1100 continues to block 1126. Otherwise, method 1100 continues to block 1120.

In block 1120, merger 128 invokes LLVM PostDominatorTree analysis to check whether ExitBB post dominates entry BB. In response to determining that ExitBB does not post dominate entry BB, method 1100 continues to block 1126. Otherwise, method 1100 continues to block 1122.

In the example of FIG. 11, merger 128 determines whether intrinsic pairs comply with merge criteria as set forth in blocks 1104, 1106, 1118, and 1110. With the merge criteria having been met, merger 128 is capable of merging the designated intrinsic pairs.

In block 1122, merger 128 gets the minimum execution intervals in the single entry, singe exit region (e.g., the MinInterval).

In block 1124, merger 128 encodes the merged intrinsic pair. For example, merger 128 encodes both the analyzed execution phase information and the MinInterval in the begin intrinsic and inserts the begin intrinsic right before (e.g., immediately prior to) the first non-phi instruction in the entry BB. Merger 128 encodes the end intrinsic with taking the begin intrinsic as an input and inserts the end intrinsic right before (e.g., immediately prior to) the terminator in the ExitBB. For all end intrinsics in the BBs of the single entry, single exit region and the resided BB post dominates the entry BB, inserts the end intrinsics and the begin intrinsics into the merged set. For example, merger 128 after merging each of the intrinsic pairs as described, places each of the intrinsic pairs that have been merged into the merged set.

In block 1126, merger 128 erases all of the intrinsics collected or in the merged set from the function. For example, as illustrated in the example of FIG. 8, the intrinsic pairs shown are newly created during the merging phase and the old % b0, % b1 pairs are removed.

FIG. 12 illustrates an example implementation of a data processing system 1200. As defined herein, the term “data processing system” means one or more hardware systems configured to process data, each hardware system including at least one processor and memory, wherein the processor is programmed with computer-readable instructions that, upon execution, initiate operations. Data processing system 1200 can include a processor 1202, a memory 1204, and a bus 1206 that couples various system components including memory 1204 to processor 1202.

Processor 1202 may be implemented as one or more hardware processors. In an example, processor 1202 is implemented as a central processing unit (CPU). Processor 1202 may be implemented as one or more circuits capable of carrying out instructions contained in program code. The circuit may be an integrated circuit or embedded in an integrated circuit. Processor 1202 may be implemented using a complex instruction set computer architecture (CISC), a reduced instruction set computer architecture (RISC), a vector processing architecture, or other known architectures. Example processors include, but are not limited to, processors having an x86 type of architecture (IA-32, IA-64, etc.), Power Architecture, ARM processors, and the like.

Bus 1206 represents one or more of any of a variety of communication bus structures. By way of example, and not limitation, bus 1206 may be implemented as a Peripheral Component Interconnect Express (PCIe) bus. Data processing system 1200 typically includes a variety of computer system readable media. Such media may include computer-readable volatile and non-volatile media and computer-readable removable and non-removable media.

Memory 1204 can include computer-readable media in the form of volatile memory, such as random-access memory (RAM) 1208 and/or cache memory 1210. Data processing system 1200 also can include other removable/non-removable, volatile/non-volatile computer storage media. By way of example, storage system 1212 can be provided for reading from and writing to a non-removable, non-volatile magnetic and/or solid-state media (not shown and typically called a “hard drive”). Although not shown, a magnetic disk drive for reading from and writing to a removable, non-volatile magnetic disk (e.g., a “floppy disk”), and an optical disk drive for reading from or writing to a removable, non-volatile optical disk such as a CD-ROM, DVD-ROM or other optical media can be provided. In such instances, each can be connected to bus 1206 by one or more data media interfaces. Memory 1204 is an example of at least one computer program product.

Memory 1204 is capable of storing computer-readable program instructions that are executable by processor 1202. For example, the computer-readable program instructions can include an operating system, one or more application programs, other program code, and program data. The computer-readable program instructions may include an HLS compiler that, when executed, is capable of performing the various operations described herein and/or one or more EDA tools that, when executed, is/are capable of performing a design flow on a circuit design as described herein. In the example, memory 1204 may store framework 100 of FIG. 1, which may be executed by processor 1202 to perform the operations described herein.

Accordingly, processor 1202, in executing the computer-readable program instructions, is capable of performing the various operations described herein that are attributable to a computer. It should be appreciated that data items used, generated, and/or operated upon by data processing system 1200 are functional data structures that impart functionality when employed by data processing system 1200. As defined within this disclosure, the term “data structure” means a physical implementation of a data model's organization of data within a physical memory. As such, a data structure is formed of specific electrical or magnetic structural elements in a memory. A data structure imposes physical organization on the data stored in the memory as used by an application program executed using a processor.

Data processing system 1200 may include one or more Input/Output (I/O) interfaces 1218 communicatively linked to bus 1206. I/O interface(s) 1218 allow data processing system 1200 to communicate with one or more external devices and/or communicate over one or more networks such as a local area network (LAN), a wide area network (WAN), and/or a public network (e.g., the Internet). Examples of I/O interfaces 1218 may include, but are not limited to, network cards, modems, network adapters, hardware controllers, etc. Examples of external devices also may include devices that allow a user to interact with data processing system 1200 (e.g., a display, a keyboard, and/or a pointing device) and/or other devices such as accelerator card.

Data processing system 1200 is only one example implementation. Data processing system 1200 can be practiced as a standalone device (e.g., as a user computing device or a server, as a bare metal server), in a cluster (e.g., two or more interconnected computers), or in a distributed cloud computing environment (e.g., as a cloud computing node) where tasks are performed by remote processing devices that are linked through a communications network. In a distributed cloud computing environment, program modules may be located in both local and remote computer system storage media including memory storage devices.

As used herein, the term “cloud computing” refers to a computing model that facilitates convenient, on-demand network access to a shared pool of configurable computing resources such as networks, servers, storage, applications, ICs (e.g., programmable ICs) and/or services. These computing resources may be rapidly provisioned and released with minimal management effort or service provider interaction. Cloud computing promotes availability and may be characterized by on-demand self-service, broad network access, resource pooling, rapid elasticity, and measured service.

The example of FIG. 12 is not intended to suggest any limitation as to the scope of use or functionality of example implementations described herein. Data processing system 1200 is an example of computer hardware that is capable of performing the various operations described within this disclosure. In this regard, data processing system 1200 may include fewer components than shown or additional components not illustrated in FIG. 12 depending upon the particular type of device and/or system that is implemented. The particular operating system and/or application(s) included may vary according to device and/or system type as may the types of I/O devices included. Further, one or more of the illustrative components may be incorporated into, or otherwise form a portion of, another component. For example, a processor may include at least some memory.

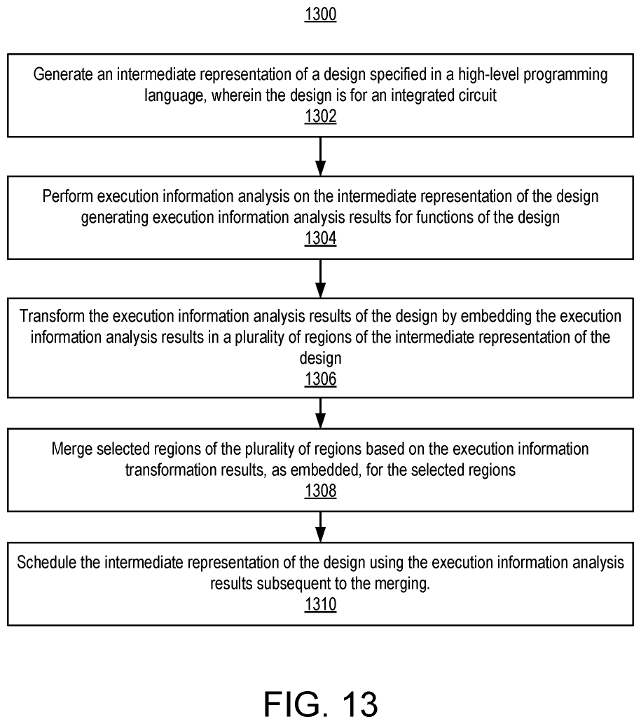

FIG. 13 illustrates an example method 1300 of certain operative features of the HLS compiler of FIG. 1 as executed by the system of FIG. 12. In block 1302, the system generates IR 106 of design 102. Design 102 may be specified in a high-level programming language. Further, design 102 is for implementation in target hardware such as an IC. In block 1304, the system performs execution information analysis on IR 106 of design 102 generating analysis results 122 for functions of design 102. In block 1306, the system transforms analysis results 122 of design 102 by embedding the analysis results 122 in a plurality of regions of IR 106. In block 1308, the system merges selected regions of the plurality of regions based on the analysis results as embedded for the selected regions. In block 1310, the system schedules IR 106 of design 102 using the analysis results subsequent to the merging.

The terminology used herein is for the purpose of describing particular embodiments only and is not intended to be limiting. Notwithstanding, several definitions that apply throughout this document are expressly defined as follows.

As defined herein, the singular forms “a,” “an,” and “the” are intended to include the plural forms as well, unless the context clearly indicates otherwise.

As defined herein, the term “approximately” means nearly correct or exact, close in value or amount but not precise. For example, the term “approximately” may mean that the recited characteristic, parameter, or value is within a predetermined amount of the exact characteristic, parameter, or value.

As defined herein, the terms “at least one,” “one or more,” and “and/or,” are open-ended expressions that are both conjunctive and disjunctive in operation unless explicitly stated otherwise. For example, each of the expressions “at least one of A, B, and C,” “at least one of A, B, or C,” “one or more of A, B, and C,” “one or more of A, B, or C,” and “A, B, and/or C” means A alone, B alone, C alone, A and B together, A and C together, B and C together, or A, B and C together.

As defined herein, the term “automatically” means without human intervention.

As defined herein, the term “computer-readable storage medium” means a storage medium that contains or stores program instructions for use by or in connection with an instruction execution system, apparatus, or device. As defined herein, a “computer-readable storage medium” is not a transitory, propagating signal per se. The various forms of memory, as described herein, are examples of computer-readable storage media. A non-exhaustive list of examples of computer-readable storage media include an electronic storage device, a magnetic storage device, an optical storage device, an electromagnetic storage device, a semiconductor storage device, or any suitable combination of the foregoing. A non-exhaustive list of more specific examples of a computer-readable storage medium may include: a portable computer diskette, a hard disk, a RAM, a read-only memory (ROM), an erasable programmable read-only memory (EPROM or Flash memory), an electronically erasable programmable read-only memory (EEPROM), a static random-access memory (SRAM), a portable compact disc read-only memory (CD-ROM), a digital versatile disk (DVD), a memory stick, a floppy disk, or the like.

As defined herein, “data processing system” means one or more hardware systems configured to process data, each hardware system including at least one hardware processor programmed to initiate operations and memory.

As defined herein, “execute” and “run” comprise a series of actions or events performed by the hardware processor in accordance with one or more machine-readable instructions. “Running” and “executing,” as defined herein refer to the active performing of actions or events by the hardware processor. The terms run, running, execute, and executing are used synonymously herein.

As defined herein, the term “if” means “when” or “upon” or “in response to” or “responsive to,” depending upon the context. Thus, the phrase “if it is determined” or “if [a stated condition or event] is detected” may be construed to mean “upon determining” or “in response to determining” or “upon detecting [the stated condition or event]” or “in response to detecting [the stated condition or event]” or “responsive to detecting [the stated condition or event]” depending on the context.

As defined herein, the term “responsive to” and similar language as described above, e.g., “if,” “when,” or “upon,” means responding or reacting readily to an action or event. The response or reaction is performed automatically. Thus, if a second action is performed “responsive to” a first action, there is a causal relationship between an occurrence of the first action and an occurrence of the second action. The term “responsive to” indicates the causal relationship.

As defined herein, the terms “individual” and “user” each refer to a human being.

As defined herein, the term “hardware processor” means at least one hardware circuit. The hardware circuit may be configured to carry out instructions contained in program code. The hardware circuit may be an integrated circuit. Examples of a hardware processor include, but are not limited to, a central processing unit (CPU), an array processor, a vector processor, a digital signal processor (DSP), a field-programmable gate array (FPGA), a programmable logic array (PLA), an application specific integrated circuit (ASIC), programmable logic circuitry, and a controller.

As defined herein, the terms “one embodiment,” “an embodiment,” “in one or more embodiments,” “in particular embodiments,” or similar language mean that a particular feature, structure, or characteristic described in connection with the embodiment is included in at least one embodiment described within this disclosure. Thus, appearances of the aforementioned phrases and/or similar language throughout this disclosure may, but do not necessarily, all refer to the same embodiment.

As defined herein, the term “output” means storing in physical memory elements, e.g., devices, writing to display or other peripheral output device, sending or transmitting to another system, exporting, or the like.

As defined herein, the term “real-time” means a level of processing responsiveness that a user or system senses as sufficiently immediate for a particular process or determination to be made, or that enables the processor to keep up with some external process.

As defined herein, the term “soft” in reference to a circuit means that the circuit is implemented in programmable logic or programmable circuitry. Thus, a “soft processor” means at least one circuit implemented in programmable circuitry that is capable of carrying out instructions embodied as program instructions.

As defined herein, the term “substantially” means that the recited characteristic, parameter, or value need not be achieved exactly, but that deviations or variations, including for example, tolerances, measurement error, measurement accuracy limitations, and other factors known to those of skill in the art, may occur in amounts that do not preclude the effect the characteristic was intended to provide.

The terms first, second, etc. may be used herein to describe various elements. These elements should not be limited by these terms, as these terms are only used to distinguish one element from another unless stated otherwise or the context clearly indicates otherwise.

A computer program product may include a computer-readable storage medium (or media) having computer-readable program instructions thereon for causing a processor to carry out aspects of the inventive arrangements described herein. Within this disclosure, the term “program code” is used interchangeably with the term “program instructions.” Computer-readable program instructions described herein may be downloaded to respective computing/processing devices from a computer-readable storage medium or to an external computer or external storage device via a network, for example, the Internet, a LAN, a WAN and/or a wireless network. The network may include copper transmission cables, optical transmission fibers, wireless transmission, routers, firewalls, switches, gateway computers and/or edge devices including edge servers. A network adapter card or network interface in each computing/processing device receives computer-readable program instructions from the network and forwards the computer-readable program instructions for storage in a computer-readable storage medium within the respective computing/processing device.

Computer-readable program instructions for carrying out operations for the inventive arrangements described herein may be assembler instructions, instruction-set-architecture (ISA) instructions, machine instructions, machine dependent instructions, microcode, firmware instructions, or either source code or object code written in any combination of one or more programming languages, including an object-oriented programming language and/or procedural programming languages. Computer-readable program instructions may include state-setting data. The computer-readable program instructions may execute entirely on the user's computer, partly on the user's computer, as a stand-alone software package, partly on the user's computer and partly on a remote computer or entirely on the remote computer or server. In the latter scenario, the remote computer may be connected to the user's computer through any type of network, including a LAN or a WAN, or the connection may be made to an external computer (for example, through the Internet using an Internet Service Provider). In some cases, electronic circuitry including, for example, programmable logic circuitry, an FPGA, or a PLA may execute the computer-readable program instructions by utilizing state information of the computer-readable program instructions to personalize the electronic circuitry, in order to perform aspects of the inventive arrangements described herein.

Certain aspects of the inventive arrangements are described herein with reference to flowchart illustrations and/or block diagrams of methods, apparatus (systems), and computer program products. It will be understood that each block of the flowchart illustrations and/or block diagrams, and combinations of blocks in the flowchart illustrations and/or block diagrams, may be implemented by computer-readable program instructions, e.g., program code.

These computer-readable program instructions may be provided to a processor of a computer, special-purpose computer, or other programmable data processing apparatus to produce a machine, such that the instructions, which execute via the processor of the computer or other programmable data processing apparatus, create means for implementing the functions/acts specified in the flowchart and/or block diagram block or blocks. These computer-readable program instructions may also be stored in a computer-readable storage medium that can direct a computer, a programmable data processing apparatus, and/or other devices to function in a particular manner, such that the computer-readable storage medium having instructions stored therein comprises an article of manufacture including instructions which implement aspects of the operations specified in the flowchart and/or block diagram block or blocks.

The computer-readable program instructions may also be loaded onto a computer, other programmable data processing apparatus, or other device to cause a series of operations to be performed on the computer, other programmable apparatus or other device to produce a computer implemented process, such that the instructions which execute on the computer, other programmable apparatus, or other device implement the functions/acts specified in the flowchart and/or block diagram block or blocks.

The flowchart and block diagrams in the Figures illustrate the architecture, functionality, and operation of possible implementations of systems, methods, and computer program products according to various aspects of the inventive arrangements. In this regard, each block in the flowchart or block diagrams may represent a module, segment, or portion of instructions, which comprises one or more executable instructions for implementing the specified operations.

In some alternative implementations, the operations noted in the blocks may occur out of the order noted in the figures. For example, two blocks shown in succession may be executed substantially concurrently, or the blocks may sometimes be executed in the reverse order, depending upon the functionality involved. In other examples, blocks may be performed generally in increasing numeric order while in still other examples, one or more blocks may be performed in varying order with the results being stored and utilized in subsequent or other blocks that do not immediately follow. It will also be noted that each block of the block diagrams and/or flowchart illustration, and combinations of blocks in the block diagrams and/or flowchart illustration, may be implemented by special purpose hardware-based systems that perform the specified functions or acts or carry out combinations of special purpose hardware and computer instructions.

The descriptions of the various embodiments of the present invention have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A method, comprising:
generating, using computer hardware, an intermediate representation of a design specified in a high-level programming language, wherein the design is for an integrated circuit;
performing, using the computer hardware, execution information analysis on the intermediate representation of the design, the execution information analysis generating analysis results for functions of the design;
transforming the analysis results of the design by embedding the analysis results in a plurality of regions of the intermediate representation of the design;
merging selected regions of the plurality of regions based on the analysis results, as embedded, for the selected regions; and
scheduling the intermediate representation of the design using the analysis results subsequent to the merging.

2. The method of claim 1, wherein the regions are single entry, single exit regions.

3. The method of claim 1, wherein the transforming comprises:
translating the analysis results into intrinsic pairs, wherein each intrinsic pair includes a begin intrinsic and an end intrinsic; and
including each intrinsic pair within the intermediate representation.

4. The method of claim 3, wherein the merging merges a first intrinsic pair corresponding to a first region with a second intrinsic pair corresponding to a second region.

5. The method of claim 4, further comprising:
first determining that the first intrinsic pair and the second intrinsic pair comply with merge criteria.

6. The method of claim 3, wherein, for each intrinsic pair, the begin intrinsic is inserted in a region immediately before a begin instruction of the region and the end intrinsic is inserted into the region immediately before an end terminator instruction of the region.

7. The method of claim 1, wherein the analysis results include phase execution information and execution interval information.

8. The method of claim 1, wherein the scheduling comprises:
scheduling one or more regions of the plurality of regions in fewer cycles based on the analysis results as embedded.

9. The method of claim 1, further comprising:
generating a circuit design from the intermediate representation as scheduled.

10. The method of claim 9, further comprising:
implementing the circuit design, as scheduled, within an integrated circuit.

11. A system, comprising:
one or more hardware processors configured to initiate operations including:
generating an intermediate representation of a design specified in a high-level programming language, wherein the design is for an integrated circuit;
performing execution information analysis on the intermediate representation of the design, the execution information analysis generating analysis results for functions of the design;
transforming the analysis results of the design by embedding the analysis results in a plurality of regions of the intermediate representation of the design;
merging selected regions of the plurality of regions based on the analysis results, as embedded, for the selected regions; and
scheduling the intermediate representation of the design using the analysis results subsequent to the merging.

12. The system of claim 11, wherein the regions are single entry, single exit regions.

13. The system of claim 11, wherein the transforming comprises:
translating the analysis results into intrinsic pairs, wherein each intrinsic pair includes a begin intrinsic and an end intrinsic; and
including each intrinsic pair within the intermediate representation.

14. The system of claim 13, wherein the merging merges a first intrinsic pair corresponding to a first region with a second intrinsic pair corresponding to a second region.

15. The system of claim 14, wherein the one or more hardware processors are configured to initiate operations further comprising:
first determining that the first intrinsic pair and the second intrinsic pair comply with merge criteria.

16. The system of claim 13, wherein, for each intrinsic pair, the begin intrinsic is inserted in a region immediately before a begin instruction of the region and the end intrinsic is inserted into the region immediately before an end terminator instruction of the region.

17. The system of claim 11, wherein the analysis results include phase execution information and execution interval information.

18. The system of claim 11, wherein the scheduling comprises:
scheduling one or more regions of the plurality of regions in fewer cycles based on the analysis results as embedded.

19. A computer program product comprising one or more computer readable storage mediums having program instructions embodied therewith, wherein the program instructions are executable by computer hardware to cause the computer hardware to initiate executable operations comprising:
generating an intermediate representation of a design specified in a high-level programming language, wherein the design is for an integrated circuit;
performing execution information analysis on the intermediate representation of the design, the execution information analysis generating analysis results for functions of the design;
transforming the analysis results of the design by embedding the analysis results in a plurality of regions of the intermediate representation of the design;
merging selected regions of the plurality of regions based on the analysis results, as embedded, for the selected regions; and
scheduling the intermediate representation of the design using the analysis results subsequent to the merging.

20. The computer program product of claim 19, wherein the scheduling comprises:
scheduling one or more regions of the plurality of regions in fewer cycles based on the analysis results as embedded.
